(19) United States
(12) Patent Application Publication
(10) Pub. No.: US 2026/0255678 A1
(43) Pub. Date: Aug. 27, 2026

(54) PIXEL STRUCTURE, DISPLAY PANEL AND DISPLAY DEVICE

(71) Applicants: HEFEI BOE DISPLAY TECHNOLOGY CO., LTD., Hefei, Anhui (CN); BOE TECHNOLOGY GROUP CO., LTD., Beijing (CN)

(72) Inventors: Min Cheng, Beijing (CN); Ke Dai, Beijing (CN); Haipeng Yang, Beijing (CN); Maoxiu Zhou, Beijing (CN); Chunxu Zhang, Beijing (CN); Xiaoting Jiang, Beijing (CN)

(73) Assignees: HEFEI BOE DISPLAY TECHNOLOGY CO., LTD., Hefei, Anhui (CN); BOE TECHNOLOGY GROUP CO., LTD., Beijing (CN)

(21) Appl. No.: 18/992,328

(22) PCT Filed: May 20, 2024
(86) PCT No.: PCT/CN2024/094158

§ 371 Date: Jan. 8, 2025

(30) Foreign Application Priority Data
Jun. 20, 2023 (CN) 202310746769.7

(51) Int. Cl. H10D 86/40; H10D 86/60

(52) U.S. Cl. CPC H10D 86/441; H10D 86/60

(57) ABSTRACT

A pixel structure, a display panel and a display device are provided. The pixel structure includes a substrate, and a first pixel, a first TFT and a first gate line that are located on one side of the substrate. The first TFT and the first pixel are connected through a first connection line. The first TFT is electrically connected to the first gate line. The pixel structure also includes: a first compensation structure. The first compensation structure is connected to each of the first TFT and the first pixel. A length direction of the first compensation structure is consistent with a length extension direction of the first gate line. The first compensation structure and the first gate line are arranged in a same layer and are not connected.

### CROSS-REFERENCE TO RELATED APPLICATION

The present application is the U.S. national phase of PCT Application No. PCT/CN2024/094158 filed on May 20, 2024, which claims priority to Chinese patent application No. 202310746769.7 filed in China on Jun. 20, 2023, the entire contents of which are incorporated herein by reference.

### TECHNICAL FIELD

The present application relates to the field of display technology, and in particular, to a pixel structure, a display panel and a display device.

### BACKGROUND

During preparation of the pixel structure, due to the difference in alignment between layers, the coupling capacitance between the pixel and the gate electrode will increase, resulting in generation of a Vertical-line (V-line) pattern.

Therefore, the current pixel structure still needs to be improved.

### SUMMARY

An object of the present disclosure is to provide a pixel structure, a display panel and a display device.

In one aspect of the present disclosure, a pixel structure is provided, which includes a substrate, a first pixel, a first Thin Film Transistor (TFT) and a first gate line, wherein the first pixel, the first TFT and the first gate line are located on one side of the substrate, the first TFT and the first pixel are connected through a first connection line, the first TFT is electrically connected to the first gate line, and the pixel structure further comprises: a second compensation structure, wherein the second compensation structure is connected to each of the first TFT and the first pixel, a length direction of the second compensation structure is consistent with a length extension direction of the first gate line, an orthographic projection of the second compensation structure onto the substrate overlaps with an orthographic projection of a common electrode signal line onto the substrate.

According to some embodiments of the present disclosure, the pixel structure further comprises a first compensation structure, wherein the first compensation structure is connected to each of the first TFT and the first pixel, a length direction of the first compensation structure is consistent with a length extension direction of the first gate line, the first compensation structure is arranged in a same layer as a source electrode and a drain electrode of the first TFT, and an orthographic projection of the first compensation structure onto the substrate overlaps with an orthographic projection of the first gate line onto the substrate.

According to some embodiments of the present disclosure, the first compensation structure is electrically connected to a pixel electrode of the first pixel, and is electrically connected to the drain electrode or the source electrode.

According to some embodiments of the present disclosure, the orthographic projection of the first compensation structure onto the substrate is located between an orthographic projection of the first pixel onto the substrate and an orthographic projection of the first gate line onto the substrate.

According to some embodiments of the present disclosure, the first compensation structure satisfies at least one of the following conditions: a size of an overlapping area between the orthographic projection of the first compensation structure onto the substrate and the orthographic projection of the first gate line onto the substrate in a length direction of the first gate line is a₁, and 1 μm≤a₁≤3 μm; a distance between an end of the first compensation structure proximate to the first pixel and an end of the first gate line proximate to the first compensation structure is b₁, and 1 μm≤b₁≤3 μm; a width of the first compensation structure is c₁, and 3 μm≤c₁≤10 μm.

According to some embodiments of the present disclosure, the second compensation structure is arranged in a same layer as the first gate line and is not connected to the first gate line.

According to some embodiments of the present disclosure, the second compensation structure is electrically connected to the pixel electrode of the first pixel, and the second compensation structure is electrically connected to the drain electrode or the source electrode of the first TFT.

According to some embodiments of the present disclosure, the pixel structure further comprises a second pixel, a second TFT and a second gate line, wherein the second pixel, the second TFT and the second gate line are located on one side of the substrate, the second TFT and the second pixel are connected through a second connection line, the second TFT is electrically connected to the second gate line, and a length of the first connection line is less than a length of the second connection line.

According to some embodiments of the present disclosure, the orthographic projection of the second compensation structure onto the substrate is located between an orthographic projection of the first gate line onto the substrate and an orthographic projection of the first pixel onto the substrate.

According to some embodiments of the present disclosure, the second compensation structure satisfies at least one of the following conditions: a distance between an end of the second compensation structure proximate to the first gate line and the first gate line is a₂, and 5 μm≤a₂≤15 μm; in a length direction of the second compensation structure, an end of the second compensation structure distal to the first TFT extends beyond the common electrode signal line by a length of b₂, and 5 μm≤b₂≤15 μm; a width of the second compensation structure is c₂, and 3 μm≤c₂≤10 μm.

According to some embodiments of the present disclosure, the pixel structure further comprises a second pixel, a second TFT and a second gate line, wherein the second pixel, the second TFT and the second gate line are located on one side of the substrate, the second TFT and the second pixel are connected through a second connection line, the second TFT is electrically connected to the second gate line, and a length of the first connection line is less than a length of the second connection line.

According to some embodiments of the present disclosure, the first pixel and the second pixel are arranged in a length direction of the second gate line, and the first gate line and the second gate line are arranged at two sides of the first pixel and the second pixel in a length direction of a data line.

According to some embodiments of the present disclosure, the common electrode signal line is arranged between two adjacent data lines.

According to some embodiments of the present disclosure, the first TFT further comprises a transfer electrode, and the transfer electrode is connected to a pixel electrode and a drain electrode of the first TFT through a via hole.

According to some embodiments of the present disclosure, the second compensation structure is electrically connected to a drain electrode of the first TFT.

In another aspect of the present disclosure, a display panel is provided, comprising the aforementioned pixel structure.

In yet another aspect of the present disclosure, a display device is provided, comprising the aforementioned display panel.

### BRIEF DESCRIPTION OF THE DRAWINGS

The above and/or additional aspects and advantages of the present disclosure will become apparent and easily understood from the following description of the embodiments in conjunction with the following drawings, in which:

FIG. 1 shows a schematic diagram of a dual-gate driven pixel structure;

FIG. 2 shows a mechanism of generating V-line pattern;

FIG. 3 shows a schematic diagram of a pixel arrangement of a dual-gate product;

FIG. 4 shows a schematic diagram of a pixel structure according to an embodiment of the present disclosure;

FIG. 5 shows a schematic structural diagram of a first compensation structure, a data line, and a TFT according to an embodiment of the present disclosure;

FIG. 6 shows a schematic diagram of a pixel structure according to another embodiment of the present disclosure;

FIG. 7 shows a schematic structural diagram of a second compensation structure and a gate line according to an embodiment of the present disclosure;

FIG. 8 shows a schematic diagram of a pixel structure according to another embodiment of the present disclosure.

### REFERENCE NUMERALS

1: pixel structure; G100: gate line; G11: first gate line; G12: second gate line; G13: third gate line; G14: fourth gate line; D100: data line; D11: first data line; D12: second data line; D10: support area; 1A: first pixel area; 1B: second pixel area; 101: first pixel; 102: second pixel; 11: substrate; 12: transfer electrode; 121: common electrode signal line; 13: first compensation structure; 14: second compensation structure; 141: first area; 142: second area; T11: first TFT; T12: second TFT; T13: third TFT; T14: fourth TFT; T101: source electrode; T102: drain electrode; T103: gate electrode.

### DETAILED DESCRIPTION

The embodiments of the present disclosure are described in detail below. The embodiments described below are exemplary and are only used to explain the present disclosure, and should not be construed as limiting the present disclosure. If no specific techniques or conditions are specified in the embodiments, the techniques or conditions described in the literature in this field or the product instructions are used. If the manufacturer of the reagents or instruments used is not specified, they are all conventional products that can be obtained commercially.

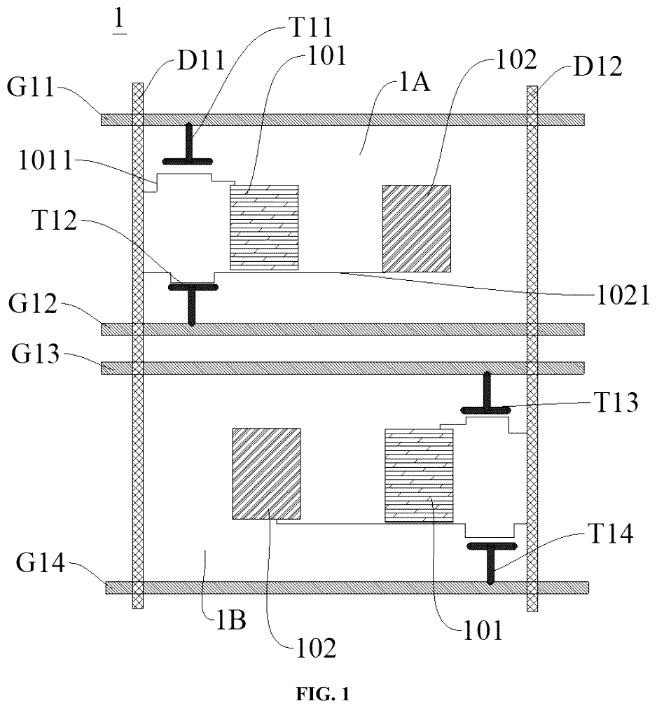

For a dual-gate driven pixel structure, due to the differences in connection lengths within the pixel, the display panel containing the dual-gate driven pixel structure is prone to the V-line pattern. For example, referring to FIG. 1, the pixel structure 1 includes a first gate line G11, a second gate line G12, a third gate line G13 and a fourth gate line G14 arranged in parallel. The distance between the first gate line G11 and the second gate line G12 is equal to the distance between the third gate line G13 and fourth gate line G14, while the second gate line G12 is adjacent to the third gate line G13. The first data line D11 and second data line D12 are sequentially arranged perpendicular to the gate line. In the first pixel area 1A, the first gate line G11 and second gate line G12 are provided with a first TFT T11 and a second TFT T12, respectively, which correspond to each other in vertical position. In the second pixel area 1B, the third gate line G13 and fourth gate line G14 are provided with a third TFT T13 and a fourth TFT T14, respectively, which correspond to each other in vertical position. The first TFT T11 is arranged on the first gate line G11, the second TFT T12 is arranged on the second gate line G12, the third TFT T13 is arranged on the third gate line G13, and the fourth TFT T14 is arranged on the fourth gate line G14.

The first pixel 101 and the second pixel 102 in the first pixel area 1A are arranged parallel to the gate line, and the first pixel 101 and the second pixel 102 in the second pixel area 1B are also arranged parallel to the gate line. The first pixel 101 in the first pixel area 1A is connected to the source electrode of the first TFT T11 through the first connection line 1011, the gate electrode of the first TFT T11 is connected to the first gate line G11, and the drain electrode of the first TFT T11 is connected to the first data line D11; the second pixel 102 in the first pixel area 1A is connected to the source electrode of the second TFT T12 through the second connection line 1021, the gate electrode of the second TFT T12 is connected to the second gate line G12, and the drain electrode of the second TFT T12 is connected to the first data line D11. The length of the first connection line 1011 is less than the length of the second connection line 1021, the first pixel 101 is a short connection pixel, and the second pixel 102 is a long connection pixel.

The first pixel 101 in the second pixel area 1B is connected to the source electrode of the third TFT T13 through the first connection line 1011, the gate electrode of the third TFT T13 is connected to the third gate line G13, and the drain electrode of the third TFT T13 is connected to the second data line D12; the second pixel 102 in the second pixel area 1B is connected to the source electrode of the fourth TFT T14 through the second connection line 1021, the gate electrode of the fourth TFT T14 is connected to the fourth gate line G14, and the drain electrode of the fourth TFT T14 is connected to the second data line D12.

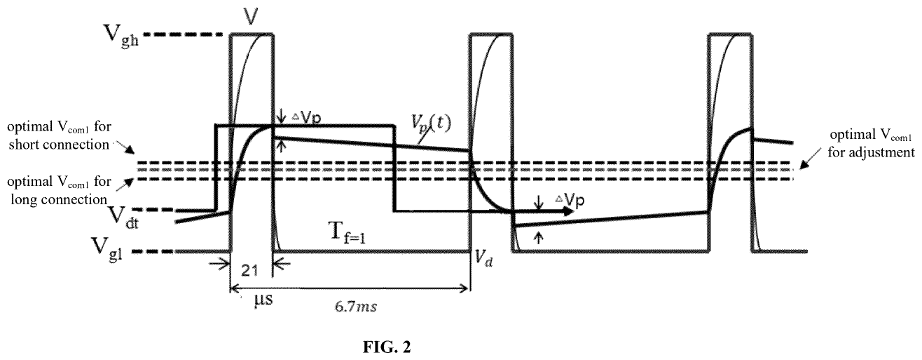

For the first pixel 101 and the second pixel 102 in the same pixel area, the coupling capacitance between the second pixel 102 and the gate electrode is larger than the coupling capacitance between the first pixel 101 and the gate electrode. The difference in coupling capacitance leads to a difference in ΔVp between the first pixel 101 and the second pixel 102, which is manifested as a different in optimal common voltages (V_{com}) (refer to FIG. 2) . In a positive frame, the pixel voltage of the second pixel 102 is pulled down more, and the first pixel 101 is relatively dark; in a negative frame, the second pixel 102 is pulled up more, and the first pixel 101 is relatively bright. When the circuit adjusts the V_{com}, it cannot simultaneously meet the respective optimal common voltages of the first pixel 101 and the second pixel 102, and a difference in brightness and darkness occurs in positive and negative frames.

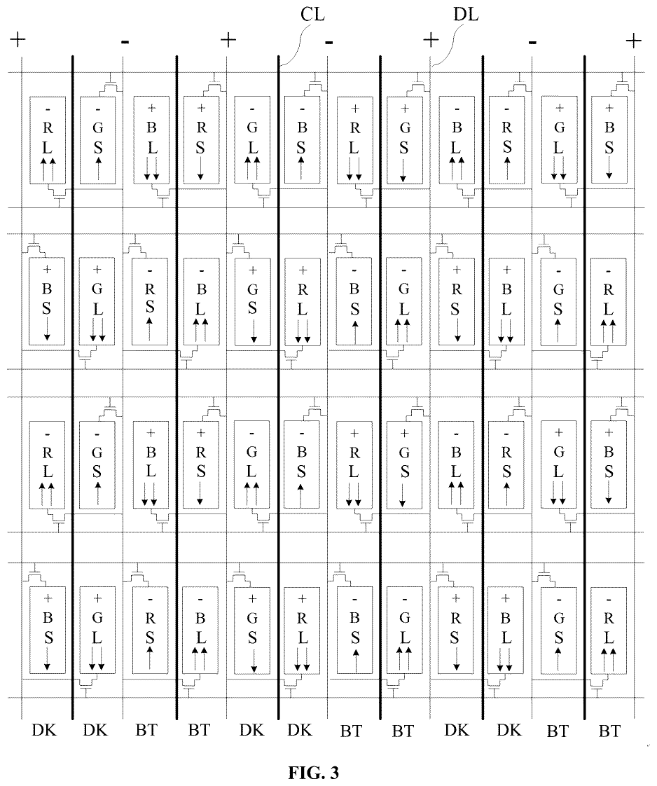

FIG. 3 is a schematic diagram of the pixel arrangement of a dual-gate product in the related art. As can be seen from FIG. 3, a dual-gate product uses a data line DL to control a short-connected pixel and a long-connected pixels adjacent to each other in a same row. At this time, since the short-connected pixel does not cross the common electrode line CL, while the long-connected pixel needs to cross the common electrode line CL, the long-connected pixel generates additional capacitance, where “L” in FIG. 3 represents a long-connected pixel, “S” in FIG. 3 represents a short-connected pixel, “↑” represents relatively bright, “↑↑” represents very bright, “↓” represents relatively dark, and “↓↓” represents very dark. The additional capacitance will cause periodic vertical stripes of a bright (BT)—bright (BT)—dark (DK)—dark (DK) arrangement to be clearly observed for a single frame (positive frame “+” or negative frame “−”) display screen when the pixel is driven by column flipping; after the frame polarity is reversed, the brightness and darkness are reversed and become a dark (DK)—dark (DK)—bright (BT)—bright (BT) arrangement, thereby achieving uniform brightness and darkness in time; however, when the users shake their head to view the screen, if a positive frame or negative frame is lost, the brightness and darkness cannot be averaged in time, thereby generating the bad V-line pattern.

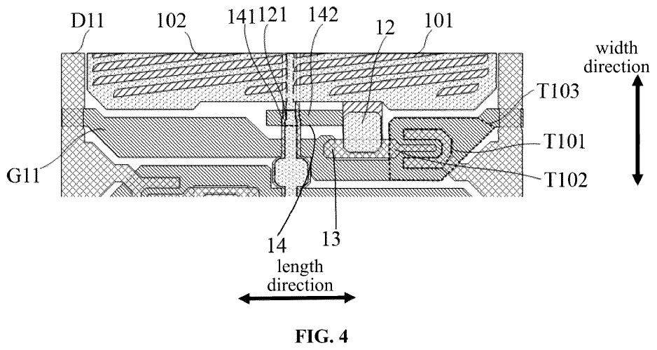

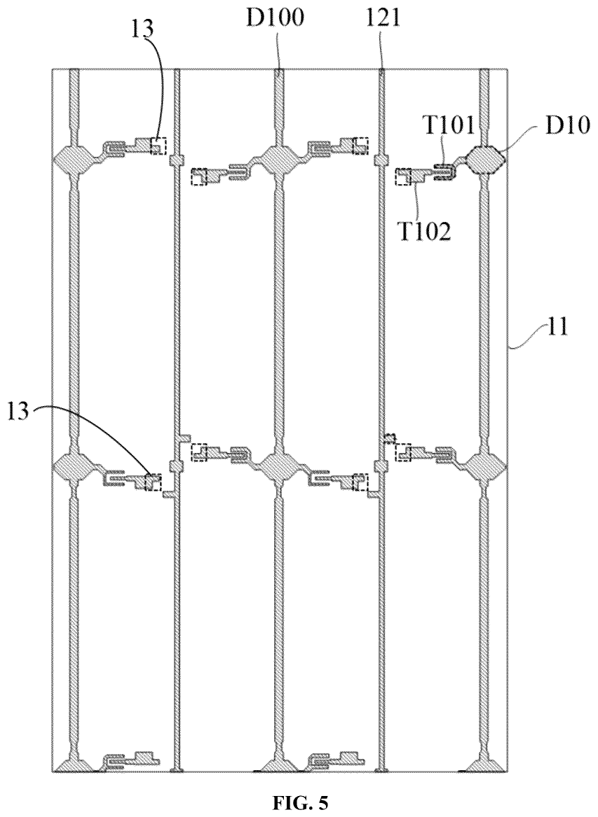

In one aspect of the present disclosure, referring to FIG. 4 and FIG. 5, a pixel structure 1 is provided, which includes a substrate 11, and a first pixel 101 a first TFT T11 and a first gate line G11 that are located on one side of the substrate 11, wherein the first TFT T11 and the first pixel 101 are connected through a first connection line 1011, and the first TFT T11 is electrically connected to the first gate line G11, and the pixel structure 1 further comprises: a first compensation structure 13, wherein the first compensation structure 13 is connected to each of the first TFT T11 and the first pixel 101, wherein the length direction of the first compensation structure 13 is consistent with the extension direction of the length of the first gate line G11, and the first compensation structure 13 is arranged in a same layer as a source electrode T101 and a drain electrode T102 of the first TFT T11. Thus, the first compensation structure 13 can compensate for the increase in coupling capacitance between the first pixel 101 and the gate electrode T103 caused by the alignment difference between the layers, further reduce the voltage difference between the first pixel 101 and the second pixel 102, and thus remove the V-line pattern.

It should be noted that, in the present application, the “same layer” refers to a layer structure formed by using the same film-forming process to form a film layer for making a specific pattern, and then using the same mask to form a layer structure through a single patterning process. That is, the single patterning process corresponds to one mask (also called a photomask). Depending on the specific pattern, the single patterning process may include multiple exposure, development or etching processes, and the specific patterns in the formed layer structure may be continuous or discontinuous, and these specific patterns may be at the same height or have the same thickness, or at different heights or have different thicknesses.

According to some embodiments of the present disclosure, referring to FIG. 1, the pixel structure 1 further includes a second pixel 102, a second TFT T12, and a second gate line G12 that are located on one side of the substrate, the second TFT T12 and the second pixel 102 are connected through a second connection line 1021, the second TFT T12 is electrically connected to the second gate line G 12, and the length of the first connection line 1011 is less than the length of the second connection line 1021. Specifically, the second pixel 102 is a long connection pixel in a dual-gate driven pixel structure, and the specific structure of the second pixel 102 is not particularly limited, and those skilled in the art may refer to the related art for design.

According to some embodiments of the present disclosure, the specific connection mode of the first compensation structure 13 with the first pixel 101 and the first TFT T11 is not particularly limited. For example, the first compensation structure 13 is electrically connected to the pixel electrode of the first pixel 101, and is electrically connected to the drain electrode T102 or the source electrode T101. According to some specific embodiments of the present disclosure, the first compensation structure 13 is directly connected to the drain electrode T102 of the first TFT T11. Specifically, the first compensation structure 13 can be directly connected to an end of the drain electrode T102 distal to the source electrode T101 (refer to FIG. 4).

According to some embodiments of the present disclosure, referring to FIG. 4, the orthographic projection of the first compensation structure 13 onto the substrate 11 overlaps with the orthographic projection of the first gate line G11 onto the substrate 11. Specifically, when one end of the first compensation structure 13 is directly connected to the drain electrode T102 of the first TFT T11, the other end of the first compensation structure 13 is directly connected to the first gate line G11 and there is an overlapping area. Thus, the coupling capacitance caused by the process fluctuation is compensated, the probability of the V-line pattern is further reduced, and the display quality is improved.

According to some embodiments of the present disclosure, with reference to FIG. 4, the orthographic projection of the first compensation structure 13 onto the substrate 11 is located between the orthographic projection of the first pixel 101 onto the substrate 11 and the orthographic projection of the first gate line G11 onto the substrate 11. Specifically, the length direction of the first compensation structure 13 is the same as the length direction of the first gate line G11, and when one end of the first compensation structure 13 in the length direction is connected to the drain electrode T103 of the first TFT T11 and the other end of the first compensation structure 13 in the length direction overlaps with the first gate line G11, the orthographic projection of the first compensation structure 13 onto the substrate 11 is spaced apart from the orthographic projection of the first pixel 101 onto the substrate 11 in the width direction of the first gate line G11. Thus, the aperture ratio of the first pixel 101 is avoided from being adversely affected.

It should be noted that the shape of the first compensation structure 13 is not particularly limited, as long as it can connect the first TFT T11 and the first pixel 101.

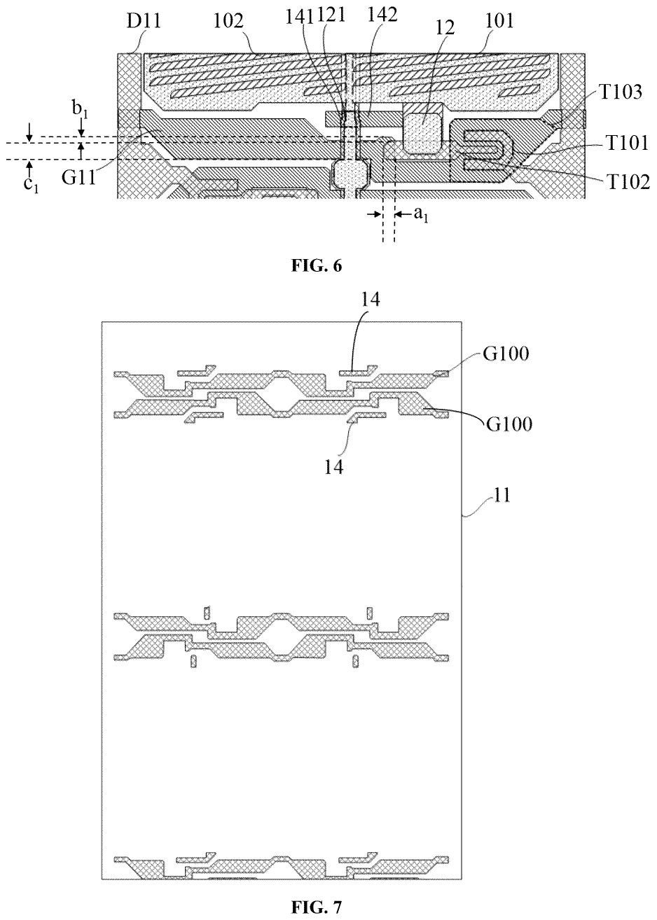

According to some embodiments of the present disclosure, referring to FIG. 6, the size of the overlapping area of the orthographic projection of the first compensation structure 13 onto the substrate 11 and the orthographic projection of the first gate line G11 onto the substrate 11 in the length direction of the first gate line G11 is a₁, and 1 μm≤a₁≤3 μm; for example, it can be 1.2 μm, 1.4 μm, 1.6 μm, 1.8 μm, 2 μm, 2.2 μm, 2.4 μm, 2.6 μm, 2.8 μm or 3 μm, etc., or can be a range composed of any of the above values. Thus, it may compensate for the increase in the coupling capacitance between the first pixel 101 and the gate electrode caused by the alignment difference between the layers, further reduce the voltage difference between the first pixel 101 and the second pixel 102 to remove the V-line pattern, reduce the process difficulty of preparing the first compensation structure 13, improve the feasibility of the process, and reduce the production cost. If the value of al is too small, the compensation effect will be affected to a certain extent due to the existence of process deviation; if the value of al is too large, the transmittance of the pixel will be reduced to a certain extent.

According to some embodiments of the present disclosure, referring to FIG. 6, the distance between one end of the first compensation structure 13 proximate to the first pixel 101 and one end of the first gate line G 11 proximate to the first compensation structure 13 is b₁, and 1μm≤b₁≤3 μm; for example, it can be 1.2 μm, 1.4 μm, 1.6 μm, 1.8 μm, 2 μm, 2.2 μm, 2.4 μm, 2.6 μm, 2.8 μm or 3 μm, etc., or can be a range composed of any of the above values. If the value of b₁ is too small, the compensation effect will be affected to a certain extent due to the existence of process deviation; if the value of bi is too large, the aperture ratio of the pixel will be reduced to a certain extent.

According to some embodiments of the present disclosure, referring to FIG. 6, the width of the first compensation structure 13 is c₁, and 3 μm≤c₁≤10 μm, for example, it can be 3 μm, 4 μm, 5 μm, 6 μm, 7 μm, 8 μm, 9 μm or 10 μm, etc., or can be a range consisting of any of the above values. If the value of c₁ is too small, the risk of wire breakage will increase during the process; if the value of c₁ is too large, the probability of over-compensation will increase to a certain extent, which affects the transmittance.

According to some embodiments of the present disclosure, the material forming the first compensation structure 13 may be metal or Indium Tin Oxide (ITO).

According to some embodiments of the present disclosure, referring to FIG. 4 and FIG. 7, the pixel structure 1 further includes: a second compensation structure 14, the second compensation structure 14 is connected to each of the first TFT T11 and the first pixel 101, the length direction of the second compensation structure 14 is consistent with the extension direction of the length of the first gate line G11, and the second compensation structure 14 is arranged in a same layer as, and is not connected to, the first gate line G11. In the present application, each pixel area includes a second compensation structure 14, and the second compensation structure 14 is connected to the first pixel 101, which can increase the coupling area of the first pixel 101, increase the capacitance of the first pixel 101, and reduce the capacitance difference between the first pixel 101 and the second pixel 102, and can reduce the voltage difference between the first pixel 101 and the second pixel 102 to 0V during the positive and negative frames, and when the circuit adjusts the V_{com}, it can simultaneously meet that the V_{com} of each the first pixel 101 and the second pixel 102 the respective optimal V_{com}, thereby removing the V-line pattern and improving the display quality.

It should be noted that the second compensation structure 14 and the first gate line G11 are disposed in the same layer and are not connected, which means that the material forming the second compensation structure 14 can be the same as the material forming the first gate line G11, but there is no overlapping area between the orthographic projection of the second compensation structure 14 onto the substrate 11 and the orthographic projection of the first gate line G11 onto the substrate 11. Specifically, the film layers for making a specific pattern can be formed by the same film forming process, and then the second compensation structure 14 and the first gate line G11 can be formed by a single patterning process using the same mask.

It should be noted that the pixel structure 1 may include a plurality of gate lines G100 and a plurality of data lines D100 (refer to FIG. 5 and FIG. 7) , the plurality of gate lines G100 are arranged in parallel and at equal intervals, the plurality of data lines D100 are arranged perpendicular to the gate lines G100 in sequence and at equal intervals, the data lines D100 may also include a support area D10, the gate lines G100 and the data lines D100 jointly define a plurality of pixel areas, each pixel area includes two pixels arranged parallel to the gate lines G100. The specific number of pixel areas is not particularly limited, and those skilled in the art may design them according to the needs of the display panel. The present application describes the pixel structure 1 by taking the example that the pixel structure 1 includes a first pixel area 1A and a second pixel area 1B.

According to some embodiments of the present disclosure, the specific connection mode between the second compensation structure 14 and the first pixel 101 and the first TFT T11 is not particularly limited. For example, the second compensation structure 14 is electrically connected to the pixel electrode of the first pixel 101, and the second compensation structure 14 is electrically connected to the drain electrode T102 or the source electrode T101 of the first TFT T11. Thus, the coupling area of the first pixel 101 can be increased, the capacitance of the first pixel 101 can be increased, and the voltage difference between the first pixel 101 and the second pixel 102 can be reduced to OV during positive and negative frames, thereby removing the V-line pattern and improving the display quality.

According to some embodiments of the present disclosure, referring to FIG. 4, the orthographic projection of the second compensation structure 14 onto the substrate 11 overlaps with the orthographic projection of the common electrode signal line 121 onto the substrate 11. Specifically, the second compensation structure 14 may include a first region 141 and a second region 142, wherein the orthographic projection of the first region 141 onto the substrate 11 is located on one side of the orthographic projection of the common electrode signal line 121 onto the substrate 11 along the length direction of the first gate line G11, and the orthographic projection of the second region 142 onto the substrate 11 is located on the other side of the orthographic projection of the common electrode signal line 121 onto the substrate 11 along the length direction of the first gate line G11. Thus, the effect of compensating the capacitance of the first pixel 101 is improved, and the probability of the occurrence of the V-line pattern is further reduced. In addition, when the pixel is connected to the gate electrode T103 or the pixel is connected to the data line D100 to become a bright spot, welding can be performed in the overlapping area of the second compensation structure 14 and the common electrode signal line 121 to make the bright spot become a dark spot, thereby improving the yield of the display panel. That is, the second compensation structure 14 increases the maintenance point for the maintenance of the pixel structure 1, thereby improving the process yield and display yield of the display panel.

According to some embodiments of the present disclosure, referring to FIG. 4, the orthographic projection of the second compensation structure 14 onto the substrate 11 is located between the orthographic projection of the first gate line G11 onto the substrate 11 and the orthographic projection of the first pixel 101 onto the substrate 11. In other words, there is no overlapping area between the second compensation structure 14 and the first gate line G11. Thus, the second compensation structure 14 can avoid the aperture area of the first pixel 101 to avoid affecting the aperture ratio of the first pixel 101.

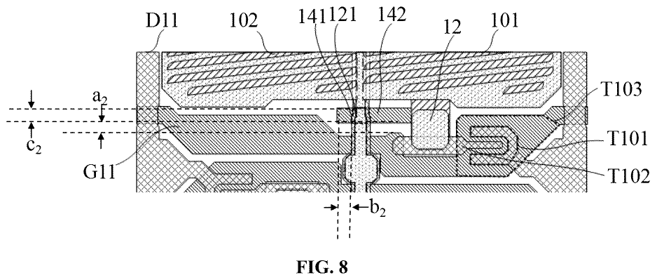

According to some embodiments of the present disclosure, referring to FIG. 8, the distance between the end of the second compensation structure 14 proximate to the first gate line G11 and the first gate line G11 is a₂, and 5 μm≤a₂≤15 μm; for example, it can be 5 μm, 7 μm, 9 μm, 11 μm, 13 μm or 15 μm, or can be any range of the above values. Thus, in addition to eliminating the V-line pattern, the process difficulty of forming the second compensation structure 14 is reduced.

According to some embodiments of the present disclosure, referring to FIG. 8, in the length direction of the second compensation structure 14, the end of the second compensation structure 14 distal to the first TFT T11 exceeds beyond the length of the common electrode signal line 121 by b₂, and 5 μm≤b₂≤15 μm; for example, it can be 5 μm, 7 μm, 9 pm, 11 μm, 13 μm or 15 μm, or can be any range of the above values. Thus, the effect of compensating the capacitance of the first pixel 101 is improved, and the probability of the occurrence of the V-line pattern is further reduced.

According to some embodiments of the present disclosure, referring to FIG. 8, the width of the second compensation structure 14 is c₂, and 3 μm≤c₂≤10 μm; for example, it can be 3 μm, 4 μm, 5 μm, 6 μm, 7 μm, 8 μm, 9 μm or 10 μm, etc., or can be any range of the above values. Thus, in addition to eliminating the V-line pattern, the process difficulty of forming the second compensation structure 14 is reduced.

According to some embodiments of the present disclosure, the type of the TFT is not particularly limited, and may be a P-type transistor or an N-type transistor.

According to some embodiments of the present disclosure, the TFT may further include a switching electrode 12, and the switching electrode 12 is connected to the pixel electrode and the drain electrode of the TFT through a via hole.

In another aspect of the present disclosure, a display panel is provided, comprising the aforementioned pixel structure 1. Thus, the display panel has all the features and advantages of the aforementioned pixel structure 1, which will not be described in detail here. In general, it has at least the advantage of good display equality.

In another aspect of the present disclosure, a display device is provided, comprising the aforementioned display panel. Thus, the display device has all the features and advantages of the aforementioned display panel, which will not be described in detail here. In general, it has at least the advantage of good display quality.

According to some embodiments of the present disclosure, the display device may be: a projector, a 3D printer, a virtual reality device, a mobile phone, a tablet computer, a television, a display, a laptop computer, a digital photo frame, a navigator, a smart watch, a fitness wristband, a personal digital assistant, or any other product or component with a display function. Optionally, the display device provided by the present disclosure includes, but is not limited to, components such as a radio frequency unit, a network module, an audio output & input unit, a sensor, a display unit, a user input unit, an interface unit, and a control chip. Optionally, the control chip is a central processing unit, a digital signal processor, a system chip (System on Chip, SoC), and the like. For example, the control chip may also include a memory, and may also include a power module, and the like, and realize power supply and signal input and output functions through additionally provided wires, signal lines, and the like. For example, the control chip may also include a hardware circuit and a computer executable code, and the like. The hardware circuit may include a conventional Very Large Scale Integration (VLSI) circuit or gate electrode array and known semiconductors or other discrete components such as logic chips and transistors; the hardware circuit may also include a field programmable gate electrode array, a programmable array logic, a programmable logic device, and the like. In addition, those skilled in the art will appreciate that the above structure does not constitute a limitation on the above display device provided in the embodiment of the present disclosure. In other words, the above display device provided in the embodiments of the present disclosure may include more or fewer of the above components, or a combination of certain components, or different component arrangements.

In the description of the present disclosure, it is necessary to understand that the orientation or positional relationship indicated by the terms “length”, “width”, etc. is based on the orientation or positional relationship shown in the accompanying drawings, and is only for the convenience of describing the present disclosure and simplifying the description, rather than indicating or implying that the device or element referred to must have a specific orientation, and be constructed and operated in a specific orientation, and therefore cannot be understood as a limitation on the present disclosure.

In addition, the terms “first” and “second” are used for descriptive purposes only and should not be understood as indicating or implying relative importance or implicitly indicating the number of the indicated technical features. Thus, a feature defined as “first” or “second” may explicitly or implicitly include one or more of the features. In the description of the present disclosure, the meaning of “plurality” is two or more, unless otherwise clearly and specifically defined.

In the present disclosure, unless otherwise clearly specified and limited, the terms “arranged”, “connected”, “coupled”, “fixed” and the like should be understood in a broad sense, for example, it can be a fixed connection, a detachable connection, or an integral connection; it can be a mechanical connection or an electrical connection; it can be a direct connection or an indirect connection through an intermediate medium, it can be the internal connection of two elements or the interaction relationship between two elements. For those of ordinary skill in the art, the specific meanings of the above terms in the present disclosure can be understood according to the specific circumstances.

In the present disclosure, unless otherwise explicitly specified and defined, the “above” or “below” relationship between the first feature and the second feature may refer to either direct contact between the first and second features or indirect contact via an intermediate medium. Furthermore, the terms “above,” “over,” and “on top of” with respect to the first feature and the second feature may mean that the first feature is directly above, obliquely above, or merely at a higher horizontal level than the second feature. Similarly, the terms “below,” “under,” and “beneath” may mean that the first feature is directly below, obliquely below, or merely at a lower horizontal level than the second feature.

In the present disclosure, the description with reference to the terms “an embodiment”, “some embodiments”, “example”, “specific example”, or “some examples” etc. means that the specific features, structures, materials or characteristics described in conjunction with the embodiment or example are included in at least one embodiment or example of the present disclosure. In the present disclosure, the schematic representations of the above terms do not necessarily refer to the same embodiment or example. Furthermore, the described specific features, structures, materials, or characteristics may be combined in an appropriate manner in one or more embodiments or examples. Additionally, where there is no conflict, those skilled in the art may combine or integrate different embodiments or examples and their respective features as described in the present disclosure.

Although the embodiments of the present disclosure have been shown and described above, it is to be understood that the above embodiments are exemplary and are not to be construed as limitations of the present disclosure. A person skilled in the art may change, modify, replace and vary the above embodiments within the scope of the present disclosure.

1. A pixel structure, comprising a substrate, a first pixel, a first Thin Film Transistor (TFT) and a first gate line, wherein the first pixel, the first TFT and the first gate line are located on one side of the substrate, the first TFT and the first pixel are connected through a first connection line, the first TFT is electrically connected to the first gate line, and the pixel structure further comprises:
a second compensation structure, wherein the second compensation structure is connected to each of the first TFT and the first pixel, a length direction of the second compensation structure is consistent with a length extension direction of the first gate line, an orthographic projection of the second compensation structure onto the substrate overlaps with an orthographic projection of a common electrode signal line onto the substrate.

2.-13. (canceled)

14. The pixel structure according to claim 1, further comprising a first compensation structure, wherein the first compensation structure is connected to each of the first TFT and the first pixel, a length direction of the first compensation structure is consistent with a length extension direction of the first gate line, the first compensation structure is arranged in a same layer as a source electrode and a drain electrode of the first TFT, and an orthographic projection of the first compensation structure onto the substrate overlaps with an orthographic projection of the first gate line onto the substrate.

15. The pixel structure according to claim 14, wherein the first compensation structure is electrically connected to a pixel electrode of the first pixel, and is electrically connected to the drain electrode or the source electrode.

16. The pixel structure according to claim 14, wherein the orthographic projection of the first compensation structure onto the substrate is located between an orthographic projection of the first pixel onto the substrate and an orthographic projection of the first gate line onto the substrate.

17. The pixel structure according to claim 16, wherein the first compensation structure satisfies at least one of the following conditions:
a size of an overlapping area between the orthographic projection of the first compensation structure onto the substrate and the orthographic projection of the first gate line onto the substrate in a length direction of the first gate line is a₁, and 1 μm≤a₁≤3 μm;
a distance between an end of the first compensation structure proximate to the first pixel and an end of the first gate line proximate to the first compensation structure is b₁, and 1 μm≤b₁≤3 μm;
a width of the first compensation structure is c₁, and 3 μm≤c₁≤10 μm.

18. The pixel structure according to claim 1, wherein
the second compensation structure is arranged in a same layer as the first gate line and is not connected to the first gate line.

19. The pixel structure according to claim 18, wherein the second compensation structure is electrically connected to the pixel electrode of the first pixel, and the second compensation structure is electrically connected to the drain electrode or the source electrode of the first TFT.

20. The pixel structure according to claim 19, further comprising a second pixel, a second TFT and a second gate line, wherein the second pixel, the second TFT and the second gate line are located on one side of the substrate, the second TFT and the second pixel are connected through a second connection line, the second TFT is electrically connected to the second gate line, and a length of the first connection line is less than a length of the second connection line.

21. The pixel structure according to claim 20, wherein the orthographic projection of the second compensation structure onto the substrate is located between an orthographic projection of the first gate line onto the substrate and an orthographic projection of the first pixel onto the substrate.

22. The pixel structure according to claim 21, wherein the second compensation structure satisfies at least one of the following conditions:
a distance between an end of the second compensation structure proximate to the first gate line and the first gate line is a₂, and 5 μm≤a₂≤15 μm;
in a length direction of the second compensation structure, an end of the second compensation structure distal to the first TFT extends beyond the common electrode signal line by a length of b₂, and 5 μm≤b₂≤15 μm;
a width of the second compensation structure is c₂, and 3 μm≤c₂≤10 μm.

23. The pixel structure according to claim 1, further comprising a second pixel, a second TFT and a second gate line, wherein the second pixel, the second TFT and the second gate line are located on one side of the substrate, the second TFT and the second pixel are connected through a second connection line, the second TFT is electrically connected to the second gate line, and a length of the first connection line is less than a length of the second connection line.

24. The pixel structure according to claim 23, wherein the first pixel and the second pixel are arranged in a length direction of the second gate line, and the first gate line and the second gate line are arranged at two sides of the first pixel and the second pixel in a length direction of a data line.

25. The pixel structure according to claim 1, wherein the common electrode signal line is arranged between two adjacent data lines.

26. The pixel structure according to claim 1, wherein the first TFT further comprises a transfer electrode, and the transfer electrode is connected to a pixel electrode and a drain electrode of the first TFT through a via hole.

27. The pixel structure according to claim 1, wherein the second compensation structure is electrically connected to a drain electrode of the first TFT.

28. A display panel, comprising the pixel structure according to claim 1.

29. The display panel according to claim 28, wherein the pixel structure further comprises a first compensation structure, wherein the first compensation structure is connected to each of the first TFT and the first pixel, a length direction of the first compensation structure is consistent with a length extension direction of the first gate line, the first compensation structure is arranged in a same layer as a source electrode and a drain electrode of the first TFT, and an orthographic projection of the first compensation structure onto the substrate overlaps with an orthographic projection of the first gate line onto the substrate.

30. The display panel according to claim 29, wherein the first compensation structure is electrically connected to a pixel electrode of the first pixel, and is electrically connected to the drain electrode or the source electrode.

31. The display panel according to claim 29, wherein the orthographic projection of the first compensation structure onto the substrate is located between an orthographic projection of the first pixel onto the substrate and an orthographic projection of the first gate line onto the substrate.

32. A display device, comprising the display panel according to claim 28.
